(19) United States
(12) Patent Application Publication
(10) Pub. No.: US 2016/0234941 A1
(43) Pub. Date: Aug. 11, 2016

(54) PRINTED CIRCUIT BOARD, SEMICONDUCTOR PACKAGE AND METHOD OF MANUFACTURING THE SAME

(71) Applicant: SAMSUNG ELECTRO-MECHANICS CO., LTD., Suwon-si (KR)

(72) Inventors: Seong-Ryul CHOI, Seoul (KR); Tae-Seong KIM, Cheongju-si (KR); Bok-Hee LEE, Daejeon (KR); Yeon-Seop YU, Seongnam-si (KR)

(73) Assignee: SAMSUNG ELECTRO-MECHANICS CO., LTD., Suwon-si (KR)

(21) Appl. No.: 15/019,647

(22) Filed: Feb. 9, 2016

(30) Foreign Application Priority Data
Feb. 10, 2015 (KR) 10-2015-0020106

(51) Int. Cl. H05K 1/18; H01L 23/538; H05K 3/40; H05K 3/12; H05K 3/30; H05K 3/00

(52) U.S. Cl. CPC H05K 1/183; H05K 3/301; H05K 3/0047; H05K 3/4038; H05K 3/1275; H01L 23/5389; H01L 23/5383

(57) ABSTRACT

A printed circuit board, a semiconductor package and a method of manufacturing the same are provided. The printed circuit board includes an insulation layer, an electronic component embedded within the insulation layer, a component guide affixing the embedded electronic component at an installed position, and a circuit layer disposed in the insulation layer.

### CROSS-REFERENCE TO RELATED APPLICATIONS

This application claims the benefit under 35 USC 119(a) of Korean Patent Application No. 10-2015-0020106, filed on Feb. 10, 2015, in the Korean Intellectual Property Office, the entire disclosure of which is incorporated herein by reference for all purposes.

### BACKGROUND

1. Field

The following description relates to a printed circuit board, a semiconductor package and a method of manufacturing the same.

2. Description of Related Art

Generally, to form a packaging substrate, integrated chips or electronic components are disposed on a board. The board may be made of any of various kinds of thermosetting synthetic resins, and metal wirings may be formed on one surface or both surfaces thereof. The integrated chips or electronic components are electrically connected with one another by the metal wirings. The integrated chips and electronic components are then covered by an insulation material.

Recently, there has been an increased demand for more functional, lighter, thinner and smaller electronic components, inspired by the advancement of the electronics industry. To obtain smaller and thinner products, printed circuit boards installed with these electronic components are also required to be made thinner and further integrated.

Coreless substrates have been receiving much attention to address the demand for producing thinner printed circuit boards. Coreless substrates can reduce the overall thickness and shorten the signal processing time within the printed circuit boards by removing the core substrate. As there is no core substrate in a coreless substrate, a carrier member that can function as a support is used during the manufacturing process of a coreless substrate. By forming a build-up layer, which includes a circuit layer and an insulation layer, on both surfaces of the carrier member through a common circuit forming method and then by removing the carrier member, the coreless substrates are completed by being separated to an upper substrate and a lower substrate. For instance, U.S. Patent Publication No. 2012/0037411 described an example of packaging substrate including a core board and dielectric layer unit to reduce the height of the overall structure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes an insulation layer, an electronic component embedded within the insulation layer, a component guide affixing the embedded electronic component at an installed position, and a circuit layer disposed in the insulation layer.

The circuit layer may include a circuit pattern embedded in one surface of the insulation layer.

The component guide may be embedded in one surface of the insulation layer.

The component guide and the circuit layer may be made of a same material.

The component guide may include a metal pattern disposed around the electronic component.

The metal pattern of the component guide may surround the electronic component.

The metal pattern of the component guide may include an “L” shaped bracket disposed at a corner of the electronic component.

The general aspect of the printed circuit board further includes a build-up layer disposed on the insulation layer, the build-up layer including a build-up insulation layer and a build-up circuit layer.

In another general aspect, a semiconductor package includes a printed circuit board including an insulation layer, an electronic component embedded within the insulation layer, a component guide affixing the embedded electronic component at an installed position, and a circuit layer disposed in the insulation layer, and a semiconductor device installed on the printed circuit board.

The semiconductor device may be installed on the printed circuit board with a solder bump.

According to another general aspect, a method of manufacturing a printed circuit board involves forming a circuit layer and a component guide simultaneously on one surface or both surfaces of a carrier substrate, installing an electronic component within the component guide, forming an insulation layer in such a manner that the electronic component is embedded in the insulation layer, and forming a first metal layer on the insulation layer.

The general aspect of the method may further involve, after the forming of first metal layer, separating the carrier substrate.

The general aspect of the method may further involve, after the forming of the first metal layer, forming an opening by drilling the insulation layer in such a manner that electrodes of the electronic component and the circuit layer are exposed; and forming a second metal layer in the exposed opening.

The general aspect of the method may further involve, after the separating of the carrier substrate, forming a via hole and an opening by drilling the separated insulation layer, forming a circuit layer by filling the via hole and the opening with a metallic material, and forming a solder resist layer on an exposed surface of the insulation layer.

The forming of the circuit layer and the component guide may include simultaneously patterning the circuit layer and the component guide using a lithography pattering method.

The circuit layer and the component guide may be made of a same metallic material.

A metal pattern of the component guide may be formed to surround the electronic component.

A metal pattern of the component guide may include an “L” shaped bracket to be disposed at a corner of the electronic component.

In another general aspect, a method of manufacturing a printed circuit board involves forming a circuit layer and a component guide simultaneously on a surface of a carrier substrate, positioning an electronic component within the component guide without applying an adhesive material between the component guide and the electronic component, and embedding the electronic component in the printed circuit board by covering the electronic component and the component guide with an insulation layer.

The forming of the circuit layer and the component guide may involve simultaneously patterning the circuit layer and the component guide using a lithography pattering method.

Other features and aspects will be apparent from the following detailed description, the drawings, and the claims.

### BRIEF DESCRIPTION OF DRAWINGS

FIG. 1 is a cross-sectional view illustrating an example of a printed circuit board.

FIG. 2 is cross-sectional view illustrating another example of a printed circuit board.

FIG. 3 is a cross-sectional view illustrating another example of a printed circuit board.

FIG. 4 is a diagram illustrating an example of a semiconductor package including the printed circuit board shown in FIG. 1.

FIGS. 5A through 5I are cross-sectional views sequentially illustrating an example of a method of manufacturing a printed circuit board.

FIG. 6 is a top view illustrating an example of a pattern shape of the component guide shown in FIG. 1.

FIG. 7 is a top view illustrating another example of a pattern shape of the component guide shown in FIG. 1.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

Hereinafter, certain embodiments of the present disclosure will be described in detail with reference to the accompanying drawings.

### Printed Circuit Board

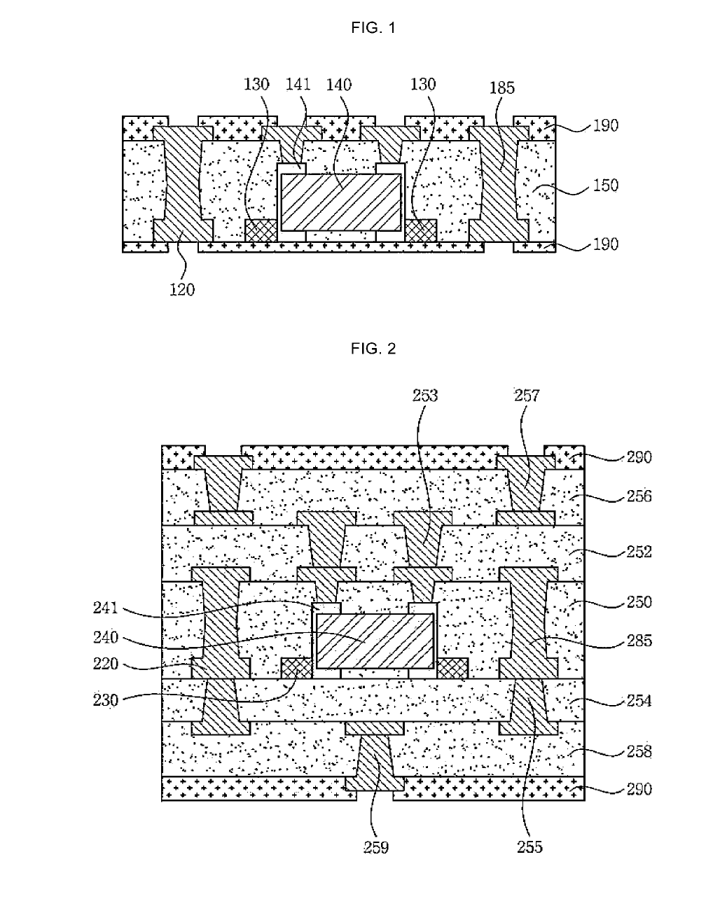

FIG. 1 illustrates a cross-sectional view of an example of a printed circuit board. Referring to FIG. 1, a printed circuit board 100 includes an insulation layer 150, an electronic component embedded within the insulation layer 150, a component guide 130 disposed to affix the embedded electronic component 140 at an installed position, circuit layers 120, 185 formed in the insulation layer 150, and a solder resist layer 190.

The insulation layer 150 is formed to have the electronic component 140 embedded therein. The insulation layer 150 may be made of a thermosetting or thermoplastic polymer material, a ceramic, an organic or inorganic composite material, or any resin having glass fiber impregnated therein. According to one example, the insulation layer 150 may be made of a polymer resin. The polymer resin may include an epoxy insulation resin, for example, flame retardant 4 (FR-4), bismaleimide triazine (BT) or an ajinomoto build-up film (ABF). Alternatively, the polymer resin may include a polyimide resin. However, the material for the insulation layer 150 may not be limited to these examples.

Referring to FIG. 1, the insulation layer 150 has a via 185, which penetrates the insulation layer 150 in a thickness direction, and a micro via, which is formed for connection with an electrode of the embedded electronic component 140. The via 185 and the micro via may be formed therein using a YAG laser or a CO₂ laser.

The circuit layer 120 may be formed before the insulation layer 150 is formed, using a subtractive process, an additive process, a semi-additive process (SAP), or a modified semi-additive process (MSAP). In this example, a subtractive process may use an etching resist to selectively remove a metallic material formed on a coreless carrier substrate (not shown), and an additive process may use electroless copper plating and electrolytic copper plating. Thereafter, the insulation layer 150 is formed on the carrier substrate having the circuit layer 120 formed thereon. After the insulation layer 150 is formed, the circuit layer 120 remains embedded in the insulation layer 150 by separating the carrier substrate.

The component guide 130 is formed by patterning the metallic material at the same time when the circuit layer 120 is formed. That is, the component guide 130 is formed by patterning the same material as that of the circuit layer 120 at the same time of forming the circuit pattern 120. In this example, the component guide 130 is formed to have a width and a height of the pattern according to an area of the electronic component 140, to provide a tight fit for the electronic component 140.

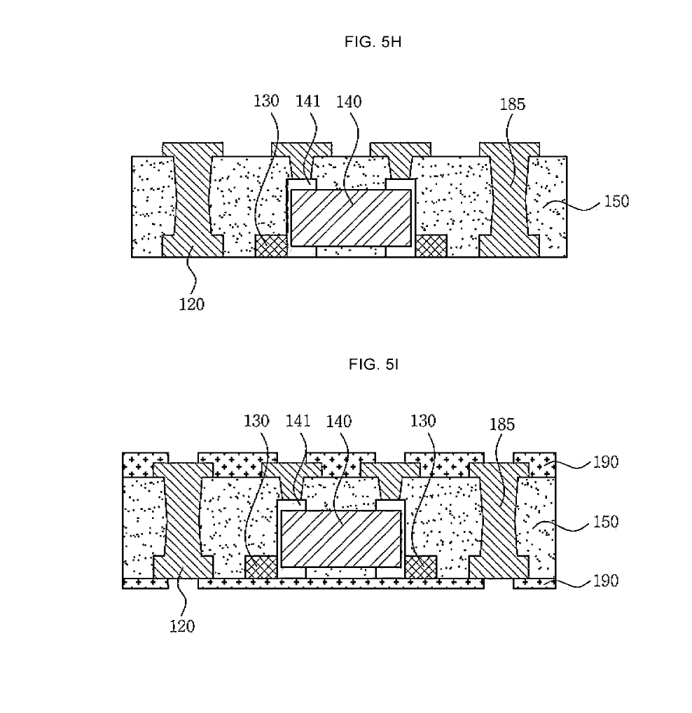

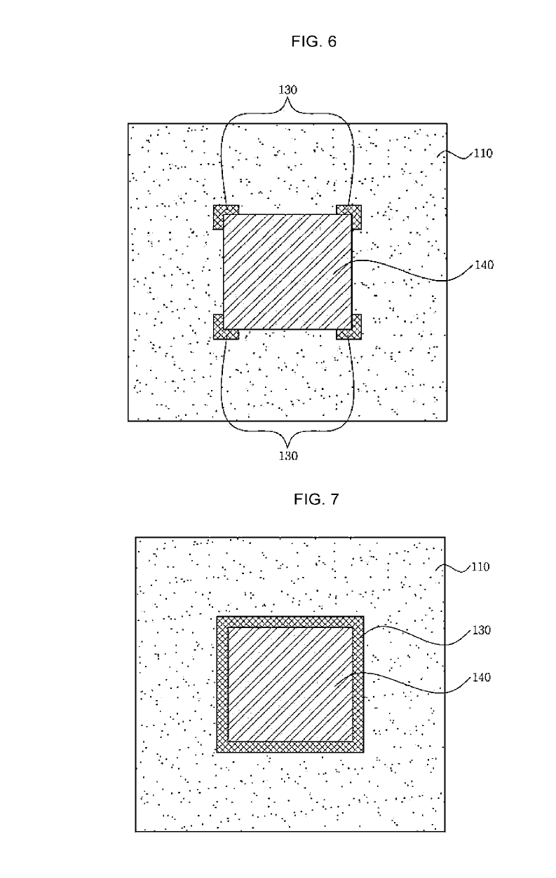

Referring to FIGS. 6 and 7, the component guide 130 is formed as a metal pattern around an area where the electronic component 140 is installed. The metal pattern may be patterned in a rectangular shape, as shown in FIG. 7, or in an “L” shaped bracket at each corner of the electronic component, as shown in FIG. 6.

Accordingly, by inserting the electronic component 140 in the component guide 130, the electronic component 140 may be stabilized within the substrate without using the conventional method of embedding an electronic component using an adhesive material, thereby saving the cost associated with using the adhesive material.

The electronic component 140 has electrodes 141 formed thereon, and the electrodes 141 of the electronic component 140 embedded within the insulation layer 150 are electrically connected with an outer circuit layer through the micro via. In this example, the electronic component 140 may be an active element, such as a transistor, an integrated circuit chip or a large scale integrated circuit chip, or a passive element, such as a resistor, a condenser or an inductor.

The solder resist layer 190 is formed on both surfaces of the insulation layer 150 and has an opening formed therein such that the via 185 and the circuit pattern 120 connected with the electrodes 141 of the electronic component 140 are exposed.

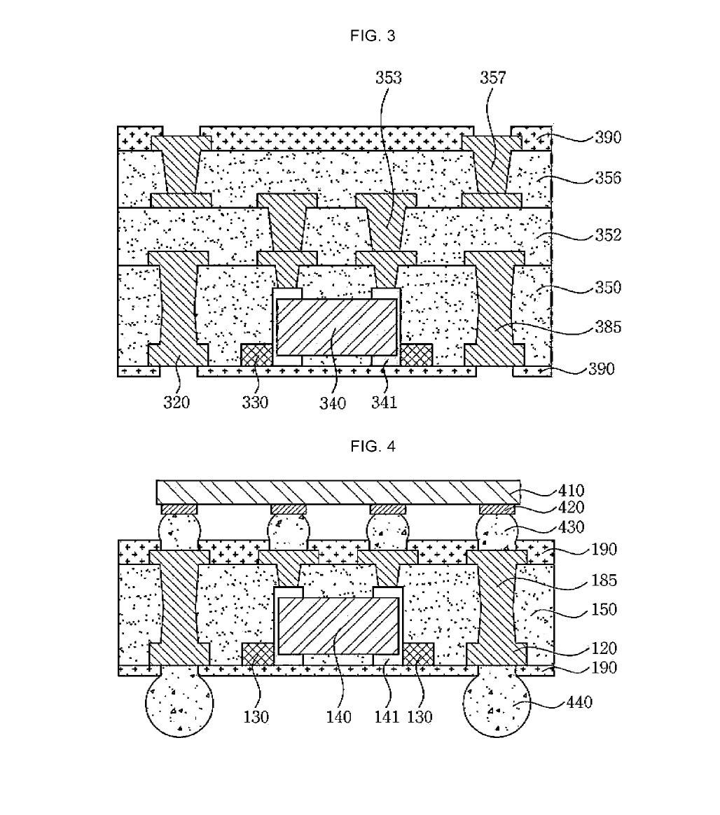

FIG. 2 illustrates a cross-sectional view of another example of a printed circuit board. In the example illustrated in FIG. 2, the printed circuit board has a build-up layer formed symmetrically above and below the insulation layer.

Referring to FIG. 2, the printed circuit board includes: an insulation layer 250; an electronic component 240 embedded within the insulation layer 250; a component guide 230 disposed such that the embedded electronic component 240 is affixed at an installed position; and a build-up layer including circuit layers 220, 285 formed in the insulation layer 250, and build-up insulation layers 252, 254, 256, 258 and build-up circuit layers 253, 255, 257, 259 formed on both surfaces of the insulation layer 250.

The build-up layer also includes a solder resist layer 290, which includes an opening for exposing an outermost circuit layer, formed on an outermost side thereof.

Here, descriptions of elements that are redundant with the example shown in FIG. 1 will be omitted.

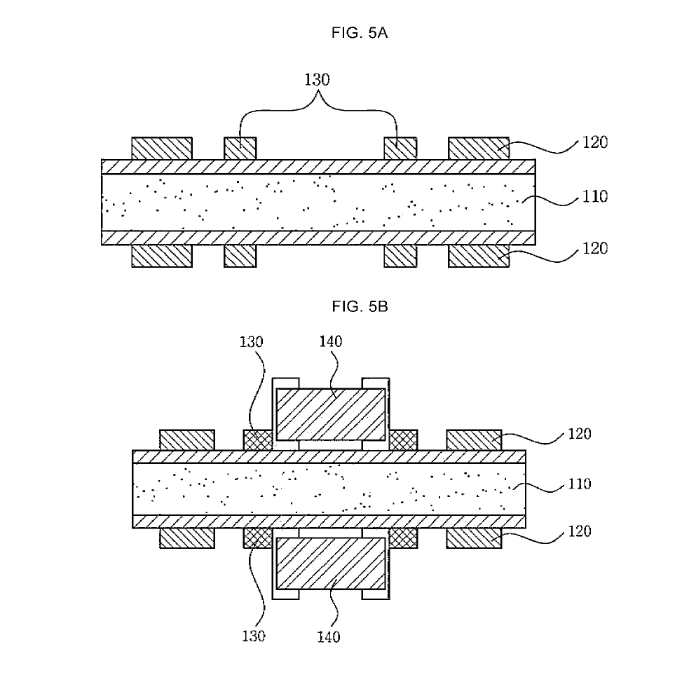

FIG. 3 illustrates a cross-sectional view of another example of a printed circuit board. Referring to FIG. 3, the printed circuit board according to this example includes: an insulation layer 350; an electronic component 340 embedded within the insulation layer 350; a component guide 330 disposed such that the embedded electronic component 340 is affixed at an installed position; and a build-up layer including circuit layers 320, 385 formed in the insulation layer 350, and build-up insulation layers 352, 356 and build-up circuit layers 353, 357 formed on one surfaces of the insulation layer 350. In this example, the build-up layer is formed above the insulation layer 350 in which the electronic component 340 is embedded.

Moreover, the build-up layer includes a solder resist layer 390 further formed on an outermost side thereof. The solder resist layer 390 have an opening for exposing an outermost circuit layer.

Here, descriptions of elements that are redundant with the example shown in FIG. 1 will be omitted.

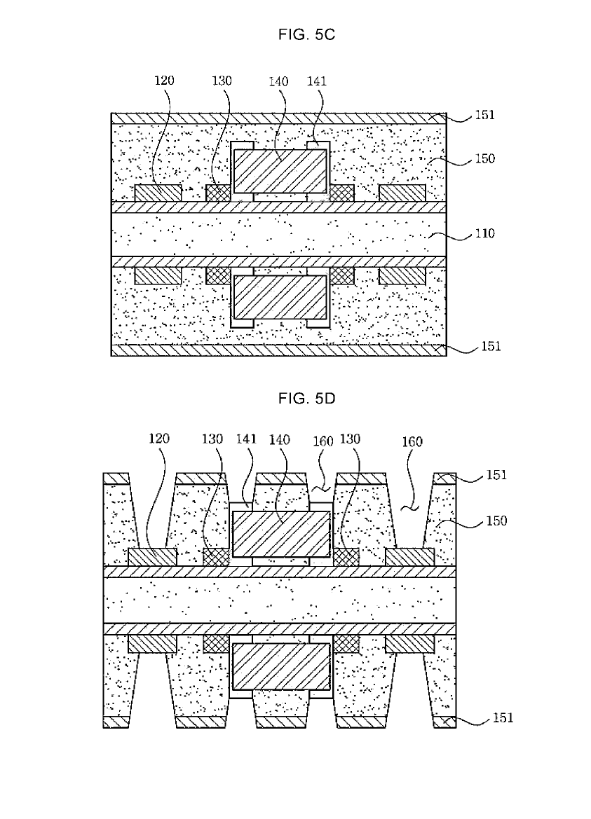

FIG. 4 illustrates an example of a semiconductor package in which the printed circuit board shown in FIG. 1 is applied.

Referring to FIG. 4, in the semiconductor package, a semiconductor device 410 is installed on the printed circuit board, which includes the insulation layer 150, the electronic component 140 embedded within the insulation layer 150, the component guide 130 disposed such that the embedded electronic component 140 is affixed at the installed position, and the circuit layers 120, 185 as well as the solder resist layer 190. In this example, the semiconductor device 410 is installed on the printed circuit board by way of a connection pad 420, formed on the semiconductor device 410, and a solder bump 430, formed on the printed circuit board.

Here, descriptions of elements that are redundant with the example shown in FIG. 1 will be omitted.

### Method of Manufacturing Printed Circuit Board

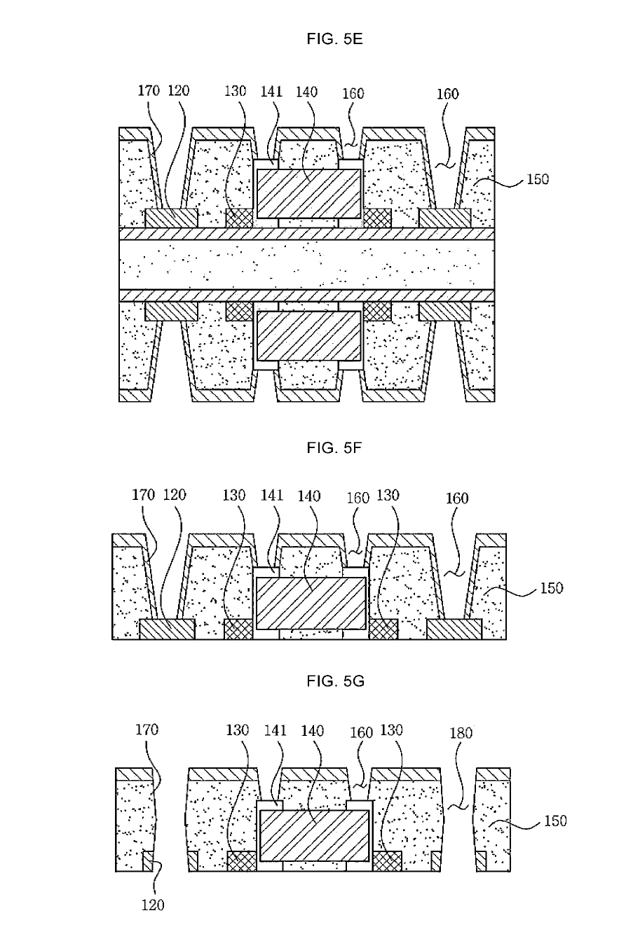

FIGS. 5A through 5I illustrate processes used in an example of a method of manufacturing a printed circuit board by illustrating cross-sectional views of the printed circuit board during the manufacturing process. As illustrated in FIGS. 5A to 5I, the method of manufacturing a printed circuit board includes: patterning and forming a circuit layer and a component guide simultaneously on one surface or both surfaces of a carrier substrate; installed an electronic component within the component guide; forming an insulation layer on the carrier substrate; forming a first metal layer on the insulation layer; forming an opening by drilling the insulation layer such that electrodes of the electronic component and the circuit layer are exposed; forming a second metal layer in the opening; separating the carrier substrate; forming a via hole and an opening b drilling the separated insulation layer; forming a circuit layer by filling the via hole and the opening with a metallic material; and forming a solder resist layer on an exposed surface of the insulation layer. Hereinafter, each of the processes used in the method of manufacturing a printed circuit board according to this example will be described in detail. The printed circuit board obtained by this example is shown in FIGS. 1 and 4, and any redundant descriptions will be omitted.

Referring to FIG. 5A, a circuit layer 120 and a component guide 130 are formed by simultaneously patterning a metallic material layer formed on one surface or both surfaces of a carrier substrate. In this example, the circuit layer 120 and the component guide 130 are made of a same material. The circuit layer 120 and the component guide 130 may be formed using a lithography patterning method. Alternately, the circuit layer 120 and the component guide 130 may be formed by depositing the metallic material layer and then applying a subtractive process that uses an etching resist to selectively remove the metallic material layer, an additive process that uses electroless copper plating and electrolytic copper plating, a semi-additive process (SAP), or a modified semi-additive process (MSAP).

In this example, a resin insulation material is used for the carrier substrate. The resin insulation material may be a thermosetting resin, such as epoxy resin, or a thermoplastic resin, such as polyimide.

In this example, the component guide 130 is formed to have a width and a height of a pattern according to an area of an electronic component 140.

Moreover, as shown in FIGS. 6 and 7, the component guide 130 is formed as a metal pattern around an area where the electronic component 140 is installed, by being patterned in a rectangular shape or in an “L” shaped bracket at each corner.

Then, referring to FIG. 5B, the electronic component 140 is installed within the component guide 130. In this example, by inserting and installing the electronic component 140 in the component guide 130, the electronic component 140 may be stabilized within the substrate without using the conventional method of embedding an electronic component using an adhesive material, thereby saving the cost associated with using the adhesive material.

Next, referring to FIG. 5C, an insulation layer 150 and a first metal layer 151 are formed on the carrier substrate having the electronic component 140 installed therein. In this example, the insulation layer 150 may be laminated in a semi-hardened state so as to allow the electronic component 140 to be embedded in the insulation layer 150. The insulation layer 150 may be a prepreg, and may be made of a thermosetting material or a thermoplastic material.

Afterwards, referring to FIG. 5D, an opening 160 is formed by drilling the insulation layer 150 such that electrodes of the electronic component 140 and the circuit layer 120 are exposed. In this example, a via hole may be formed in the insulation layer 150 using a YAG laser or a CO₂ laser.

Referring to FIGS. 5E and 5F, a second metal layer 170 is formed in the exposed opening 160, and then the carrier substrate is separated. In this example, the second metal layer 170 may be made of any material, such as, for example, copper, copper foil or nickel, without a specific restriction.

Then, referring to FIG. 5G, the separated insulation layer 150 is drilled to form a micro via hole 160 such that the electrodes of the electronic component 140 and a via hole 180 are exposed. In this example, the via hole 180 may be also formed using a YAG laser or a CO₂ laser. In this example, the via hole 180 may be formed by drilling the insulation layer 150 from an upper side thereof and then drilling the insulation layer 150 again from a lower side thereof.

Next, referring to FIG. 5H, an outer circuit layer 185 is formed by filling the via hole 180 and the micro via hole 160 with a metallic material. In this example, an outer circuit layer including the via 185 may be formed through a semi-additive process (SAP) or a modified semi-additive process (MSAP). Moreover, the present disclosure is not limited thereto, and may include any of common circuit forming processes, such as the subtractive process, SAP and MSAP.

Thereafter, referring to FIG. 5I, a solder resist layer 190 having an opening formed therein is formed on an exposed surface of the insulation layer 150. According to one example, a dry film (not shown), which is an etching resist for forming the opening on the solder resist 190, is formed, and then the dry film is patterned, exposed and developed. For instance, after the adhesive property of the dry film is enhanced, the dry film is laminated, and then the dry film is exposed to light to have the dry film selectively hardened. Then, portions of the dry film that are not hardened are dissolved by a developing solution to have the opening patterned.

Described above is an example of a printed circuit board with an electronic component fixed and installed thereon by use of a component guide instead of using an adhesive material. During an example of a method of manufacturing the printed circuit board, an electronic component is fixed and installed using a component guide without applying an adhesive material. By stabilizing the electronic component within a substrate without using an adhesive material, it is possible to save the cost associated with using the adhesive material.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
an insulation layer;
an electronic component embedded within the insulation layer;
a component guide affixing the embedded electronic component at an installed position; and
a circuit layer disposed in the insulation layer.

2. The printed circuit board as set forth in claim 1, wherein the circuit layer comprises a circuit pattern embedded in one surface of the insulation layer.

3. The printed circuit board as set forth in claim 1, wherein the component guide is embedded in one surface of the insulation layer.

4. The printed circuit board as set forth in claim 1, wherein the component guide and the circuit layer are made of a same material.

5. The printed circuit board as set forth in claim 1, wherein the component guide comprises a metal pattern disposed around the electronic component.

6. The printed circuit board as set forth in claim 5, wherein the metal pattern of the component guide surrounds the electronic component.

7. The printed circuit board as set forth in claim 5, wherein the metal pattern of the component guide comprises an “L” shaped bracket disposed at a corner of the electronic component.

8. The printed circuit board as set forth in claim 1, further comprising a build-up layer disposed on the insulation layer, the build-up layer comprising a build-up insulation layer and a build-up circuit layer.

9. A semiconductor package comprising:
a printed circuit board comprising: an insulation layer; an electronic component embedded within the insulation layer; a component guide affixing the embedded electronic component at an installed position; and a circuit layer disposed in the insulation layer; and
a semiconductor device installed on the printed circuit board.

10. The semiconductor package as set forth in claim 9, wherein the semiconductor device is installed on the printed circuit board with a solder bump.

11. A method of manufacturing a printed circuit board, comprising:
forming a circuit layer and a component guide simultaneously on one surface or both surfaces of a carrier substrate;
installing an electronic component within the component guide;
forming an insulation layer in such a manner that the electronic component is embedded in the insulation layer; and
forming a first metal layer on the insulation layer.

12. The method as set forth in claim 11, further comprising, after the forming of first metal layer:
separating the carrier substrate.

13. The method as set forth in claim 11, further comprising, after the forming of the first metal layer:
forming an opening by drilling the insulation layer in such a manner that electrodes of the electronic component and the circuit layer are exposed; and
forming a second metal layer in the exposed opening.

14. The method as set forth in claim 12, further comprising, after the separating of the carrier substrate:
forming a via hole and an opening by drilling the separated insulation layer;
forming a circuit layer by filling the via hole and the opening with a metallic material; and
forming a solder resist layer on an exposed surface of the insulation layer.

15. The method as set forth in claim 11, wherein the forming of the circuit layer and the component guide comprises simultaneously patterning the circuit layer and the component guide using a lithography pattering method.

16. The method as set forth in claim 11, wherein the circuit layer and the component guide are made of a same metallic material.

17. The method as set forth in claim 11, wherein a metal pattern of the component guide is formed to surround the electronic component.

18. The method as set forth in claim 11, wherein a metal pattern of the component guide comprises an “L” shaped bracket to be disposed at a corner of the electronic component.

19. A method of manufacturing a printed circuit board, comprising:
forming a circuit layer and a component guide simultaneously on a carrier substrate;
positioning an electronic component within the component guide without applying an adhesive material between the component guide and the electronic component; and
embedding the electronic component in the printed circuit board by covering the electronic component and the component guide with an insulation layer.

20. The method as set forth in claim 19, wherein the forming of the circuit layer and the component guide comprises simultaneously patterning the circuit layer and the component guide using a lithography pattering method.
